(19) United States
(12) Patent Application Publication
(10) Pub. No.: US 2009/0301393 A1
(43) Pub. Date: Dec. 10, 2009

(54) VACUUM COATING APPARATUS

(76) Inventor: Jens William Larsen, Dronninglund (DK)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/300,638

(22) PCT Filed: May 11, 2007
(86) PCT No.: PCT/DK07/00224

§ 371 Date: Jul. 21, 2009

(30) Foreign Application Priority Data
May 13, 2006 (DK) PA 2006 00672

(51) Int. Cl. C23C 14/00; C23C 14/35

(52) U.S. Cl. 118/50.1; 204/298.09

(57) ABSTRACT

An apparatus for vacuum coating, including a vacuum chamber including at least one magnetron (2), each magnetron holding a target including at least one metal sheet (24) from which metal particles are transferred to a surface of a receiving item. The magnetrons have a channel system for supplying and discharging coolant. The magnetrons (2) preferably include an elongated body having mutually movable and interacting parts which are an outer part (14) having a longitudinal cavity and which outwardly at opposite sides of the cavity has inwardly facing holder members (12) and an inner part (18) located in the longitudinal cavity. these inner parts outwardly along opposing sides has edge parts for interacting with the holder members for clamping the target (24), which in size is adapted to the magnetron (2). Each of the magnetrons includes means for displacing the inner part (18) in relation to the outer part (14).

### BACKGROUND OF THE INVENTION

1. Field of the Invention

The present invention concerns an apparatus for vacuum coating.

2. Description of the Prior Art

Prior art apparatuses for vacuum coating or sputtering include one or more magnetrons in which are arranged plate-shaped “targets,” usually in the form of metal sheets, from where metal particles are transferred by vacuum coating or sputtering to the item to be provided with a metal coating. That is, it goes without saying that the targets are often worn down and have to be replaced.

With the prior art apparatuses for vacuum coating or sputtering, it is a very time-consuming and tedious work to substitute targets, since it is most often required that the magnetrons largely have to be disassembled in order to replace targets.

### SUMMARY OF THE INVENTION

The invention provides an improved apparatus of the kind described above, and which by means of simple technical measures provides a very significant saving of time when replacing targets.

The apparatus according to the invention utilizes magnetrons having preferably an elongated body with mutually movable and interacting parts, namely an outer part having a longitudinal cavity and which outwards at opposite sides of the cavity are inwardly facing holder members, and an inner part disposed in the longitudinal cavity, and which outwardly along opposing sides has edge parts for interacting with the holder members for clamping the target. The size of the target is adapted to the magnetron with each of the magnetrons including means for displacing the inner part in relation to the outer part. By means of simple technical measures, it is hereby possible to achieve a very significant saving of time when replacing targets.

The apparatus according to the invention is preferably designed so that the inner part has a longitudinal upward open concavity in which the magnet system of the magnetron is disposed, so that it is disposed under the target when this is clamped between the holder members of the outer part and the edge parts of the inner part.

The apparatus according to the invention may be designed in a particularly simple and suitable way so that the displacing means have threaded screws for interacting with threaded holes in the outer part, and which with end parts interacts with the inner part.

Alternatively, the apparatus according to the invention may so have the displacement means constituted by one or more eccentric discs that interact with the outer part and with the inner part, and which are actuated by means of a common swivel shaft with an actuator which is accessible from the outer side of the outer part.

With the intention of enabling the required movement between the inner and outer parts, the apparatus according to the invention has the cooling channels for the inner and outer parts interconnected by means of a flexible pipeline provided with fittings for pipelines to an external cooling system.

With the intention of encapsulating the magnetrons, the apparatus according to the invention includes an external cabinet with an outward longitudinal aperture opposite the target. The external cabinet includes a lid for covering the longitudinal aperture.

### BRIEF DESCRIPTION OF THE DRAWINGS

The invention is explained more closely in the following with reference to the drawing, on which:

FIG. 1 shows a side view, partly in section, of an embodiment of a magnetron for the apparatus according to the invention;

FIG. 2 shows a view of the magnetron shown in FIG. 1, as seen from below;

FIG. 3 shows a view of the magnetron shown in FIG. 1, as seen from the left;

FIG. 4 shows a sectional view of the magnetron shown in FIG. 1, with open “jaws”;

FIG. 5 shows a sectional view of the magnetron shown in FIG. 1, with closed “jaws”; and

FIG. 6 shows an enlarged view of the magnetron shown in FIG. 1, as seen from the right.

### DETAILED DESCRIPTION OF THE INVENTION

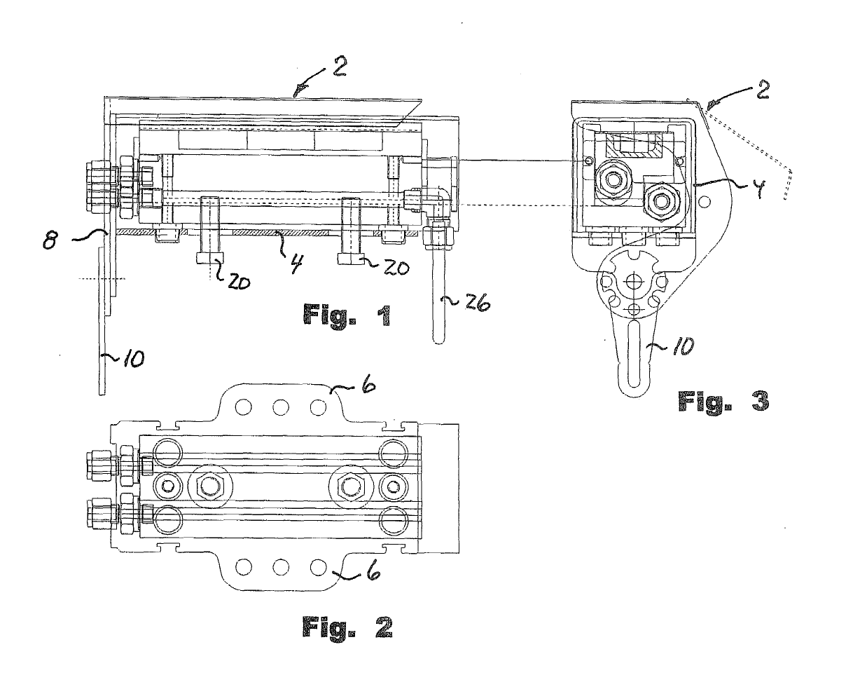

The magnetron 2 shown in FIGS. 1-3 is designed as an elongated body with an external cabinet 4 which at opposing sides at the bottom is provided with connecting flanges 6 (FIG. 2) and which at an end part 8 is provided with an angularly adjustable support arm 10 (FIG. 3), so that the magnetron 2 can be fixed internally in a vacuum chamber with desired orientation.

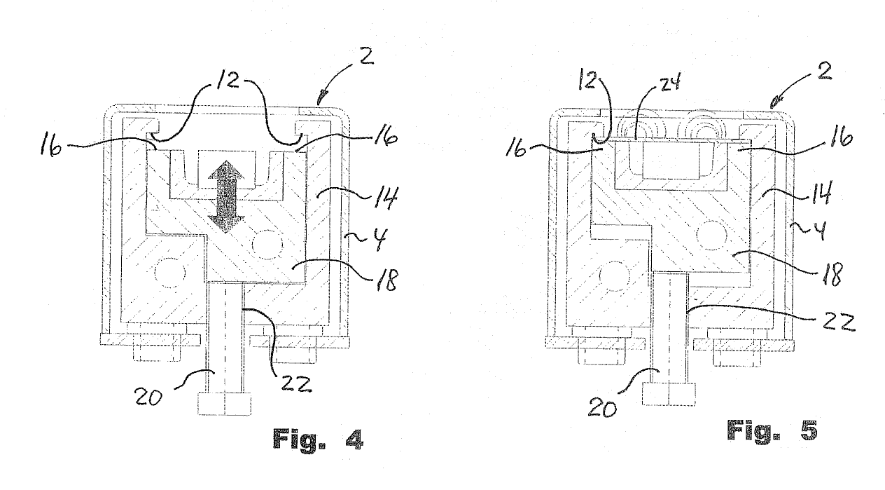

In FIG. 4, the magnetron 2 is shown with open “jaws”, that is with spacing between the upper holder members 12 of an outer part 14 and edge parts 16 of an inner part 18. By means of a threaded screw 20 engaging a threaded hole 22 in the outer part 14, the inner part 18 may be displaced upwardly in relation to the outer part 14, so that the “jaws” close around a target 24, for example a copper sheet as shown in FIG. 5, where the target 24 is fixed between the holder members 12 and the edge parts 16.

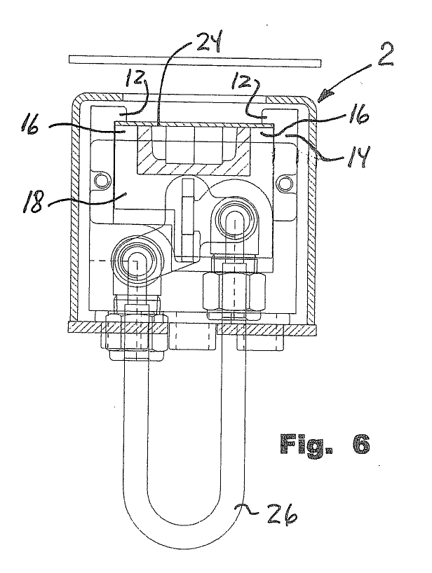

FIG. 6 shows cooling channels interconnected by means of a flexible pipeline 26 to respectively movable parts of the magnetron 2.

Alternatively, the above described means for accomplishing the mutual clamping movement between the outer part 14 and the inner part 18 may instead be constituted by one or more eccentric discs simultaneously acting between the outer part 14 and the inner part 18 for clamping the target 24 between edge parts 16 and the holder members 12. The eccentric discs may suitably be arranged on a common shaft with an actuator, which, for example, is accessible from an external side of the outer part 14.

A further alternative to the above described means for accomplishing the mutual clamping movement between the outer part 14 and the inner part 18 may be with wedges which may, from opposing outer short sides of the outer part 14, be inserted to displace the inner part 18 and thereby the edge parts 16 of the latter upwards against the upper holder members 12 of the outer part 14 for clamping the target 24 between the edge parts 16 and the holder members 12.

1-6. (canceled)

7. An apparatus for vacuum coating comprising:
a vacuum chamber including at least one magnetron, each magnetron holding a target including at least one metal sheet from which metal particles are to be transferred to surface of a receiving item, the magnetrons including a channel system for supplying and discharging coolant, wherein the magnetrons include a body with mutually movable and interacting parts, including an outer part with a cavity and which at opposite sides of the cavity has inwardly facing holder members, and an inner part disposed in the cavity, and outwardly along opposing sides includes a parts for interacting with the holder members for clamping with target, with each of magnetrons including means for displacing the inner part in relation to the outer part to hold the target.

8. An apparatus in accordance with claim 7 wherein each magnetron includes an elongated body including an elongated cavity.

9. An apparatus according to claim 7, wherein the inner part includes an upwardly facing open cavity in which a magnet system of an associated magnetron is located under the target when the target is clamped between the holder members of the outer part and the opposing sides of the inner part.

10. An apparatus according to claim 8, wherein the inner part includes an upwardly facing open cavity in which a magnet system of an associated magnetron is located under the target when the target is clamped between the holder members of the outer part and the opposing sides of the inner part.

11. An apparatus according to claim 7, wherein the displacing means comprise threaded screws which interact with threaded holes in the outer part, and with end parts of an associated magnetron interacting with the inner part.

12. An apparatus according to claim 8, wherein the displacing means comprise threaded screws which interact with threaded holes in the outer part, and with end parts of an associated magnetron interacting with the inner part.

13. An apparatus according to claim 7, wherein the means for displacing comprises at least one disc which interacts with the outer part and with the inner part, and which is actuated by a common swivel shaft by an actuator accessible from an outer side of the outer part.

14. An apparatus according to claim 9, wherein the means for displacing comprises at least one disc which interacts with the outer part and with the inner part, and which is actuated by a common swivel shaft by an actuator which accessible from an outer side of the outer part.

15. An apparatus according to claim 7, wherein the system includes fittings for coupling to an external cooling system.

16. An apparatus according to claim 8, wherein the system includes fittings for coupling to an external cooling system.

17. An apparatus according to claim 9, wherein the system includes fittings for coupling to an external cooling system.

18. An apparatus according to claim 10, wherein the system includes fittings for coupling to an external cooling system.

19. An apparatus according to claim 11, wherein the system includes fittings for coupling to an external cooling system.

20. An apparatus according to claim 12, wherein the system includes fittings for coupling to an external cooling system.

21. An apparatus according to claim 13, wherein the system includes fittings for coupling to an external cooling system.

22. An apparatus according to claim 14, wherein the system includes fittings for coupling to an external cooling system.

23. An apparatus according to claim 7, wherein each magnetron includes an external cabinet with an upwardly facing longitudinal aperture opposite the target with the external cabinet including a lid for covering the longitudinal aperture.

24. An apparatus according to claim 9, wherein each magnetron includes an external cabinet with an upwardly facing longitudinal aperture opposite the target with the external cabinet including a lid for covering the longitudinal aperture.

25. An apparatus according to claim 11, wherein each magnetron includes an external cabinet with an upwardly facing longitudinal aperture opposite the target with the external cabinet including a lid for covering the longitudinal aperture.

26. An apparatus according to claim 15, wherein each magnetron includes an external cabinet with an upwardly facing longitudinal aperture opposite the target with the external cabinet including a lid for covering the longitudinal aperture.
